(19) United States
(12) Patent Application Publication
(10) Pub. No.: US 2026/0268997 A1
(43) Pub. Date: Sep. 10, 2026

(54) HBM BASE DIE INCLUDING ON-DIE DEBUG LOGGING LOGIC

(71) Applicant: Samsung Electronics Co., Ltd., Suwon-si (KR)

(72) Inventors: Hyoun Kwon JEONG, Pleasanton, CA (US); Soogil JEONG, Pleasanton, CA (US); Sangyeun CHO, Cupertino, CA (US)

(21) Appl. No.: 19/546,277

(22) Filed: Feb. 20, 2026

Related U.S. Application Data
(60) Provisional application No. 63/768,156, filed on Mar. 6, 2025.

(51) Int. Cl. G11C 29/44

(52) U.S. Cl. CPC G11C 29/44

(57) ABSTRACT

An HBM base die includes a plurality of HBM controller blocks each configured to manage command scheduling and data flow between a host interface and one or more memory devices of an HBM stack; a 3D DRAM PHY coupled to the one or more memory devices through a plurality of TSVs; a die-to-die interconnect configured to communicate with an adjacent die within a multi-die package; an NoC interconnect configured to couple internal subsystems of the HBM base die; and on-die debug logic comprising: a RISC microprocessor coupled to the NoC interconnect; an SRAM coupled to the RISC microprocessor and configured as a circular log buffer; and a DMA engine configured to transfer debug log data from the SRAM to a reserved memory region defined by a system bus mapping circuit; wherein the RISC microprocessor is configured to collect operational status information from one or more of the HBM controller blocks, the 3D DRAM PHY, and the die-to-die interconnect, timestamp the collected information, and store timestamped log entries in the SRAM.

### CROSS-REFERENCE TO RELATED APPLICATION

This application claims the benefit of priority under 35 U.S.C. § 119(e) to U.S. Provisional Patent Application Ser. No. 63/768,156, filed Mar. 6, 2025, the entire disclosure of which is incorporated herein by reference in its entirety as if fully set forth herein.

### TECHNICAL FIELD

The subject matter disclosed herein relates to semiconductor memory systems and, more particularly, to high-bandwidth memory (HBM) base dies that integrate on-die debug logging logic for real-time monitoring and analysis of HBM operational parameters.

### BACKGROUND

Conventional HBM systems rely on external host processors or boundary-scan interfaces for debug and performance monitoring. These methods provide limited visibility into timing, thermal, and internal bus activities of the HBM stack, and they typically interrupt normal memory operation or require specialized test modes. Moreover, existing HBM base dies include MBIST/IEEE1500 circuitry configured for manufacturing tests only, and not for performing continuous runtime logging or analytics. As HBM systems scale to terabytes per second of aggregate bandwidth, real-time, autonomous debug logging within the memory device itself becomes increasingly necessary to diagnose transient faults and optimize memory scheduling and thermal management.

### SUMMARY

An example embodiment provides a high-bandwidth memory (HBM) base die that includes integrated debug logging logic for in-situ monitoring and reporting of one or more operational parameters of an HBM stack. The debug logging logic may include a RISC microprocessor, a direct memory access (DMA) engine, and static random-access memory (SRAM) coupled through an on-die network-on-chip (NoC) interconnect. The RISC microprocessor may periodically collect debug information from one or more core memory dies of the HBM stack, wherein the one or more core memories are accessed via a 3D DRAM physical interface (PHY) of the base die. The 3D DRAM physical interface (PHY) may comprise one or more through silicon via—physical interface (TSV-PHY) circuits that terminate at a TSV landing zone for communicating with the one or more core memory dies of the HBM stack. The RISC microprocessor may associate the collected debug information with one or more corresponding timestamps, and store the information in a ring buffer within the SRAM. The DMA engine may periodically, or in response to a buffer-full condition, transfer the collected debug information to a reserved memory space of the HBM stack or to a host device. The collected debug information may be associated with any of traffic, queuing, power, thermal, or physical-layer status of the HBM controller, the TSV-PHY circuits, or a die-to-die interconnect, thereby enabling fine-grained visibility into HBM behavior during runtime without host intervention.

In one embodiment, a method of operating a high-bandwidth memory (HBM) base die including a near-memory computing subsystem comprises initializing, by a Reduced Instruction Set Computer (RISC) microprocessor on the HBM base die, a debug logging buffer in an on-die static random-access memory (SRAM); collecting, by the RISC microprocessor, operational status information from one or more subsystems of the HBM base die, the one or more subsystems including at least one HBM controller, a 3D DRAM physical interface (PHY), and a die-to-die interconnect; timestamping the collected operational status information and storing the timestamped information as log entries in the debug logging buffer; determining that a flush condition is satisfied based on the debug logging buffer; and initiating, responsive to the flush condition being satisfied, a direct-memory-access (DMA) transfer from the debug logging buffer to a reserved memory space accessible to a host device.

In one embodiment, a high-bandwidth memory (HBM) base die comprises a plurality of HBM controller blocks each configured to manage command scheduling and data flow between a host interface and one or more memory devices of an HBM stack; a 3D DRAM physical interface (PHY) coupled to the one or more memory devices through a plurality of through-silicon vias (TSVs); a die-to-die interconnect configured to communicate with an adjacent die within a multi-die package; a network-on-chip (NoC) interconnect configured to couple internal subsystems of the HBM base die; and on-die debug logic comprising: a Reduced Instruction Set Computer (RISC) microprocessor coupled to the NoC interconnect; a static random-access memory (SRAM) coupled to the RISC microprocessor and configured as a circular log buffer; and
a direct-memory-access (DMA) engine configured to transfer debug log data from the SRAM to a reserved memory region defined by a system bus mapping circuit; wherein the RISC microprocessor is configured to collect operational status information from one or more of the HBM controller blocks, the 3D DRAM PHY, and the die-to-die interconnect, timestamp the collected information, and store timestamped log entries in the SRAM.

### BRIEF DESCRIPTION OF THE DRAWINGS

In the following section, the aspects of the subject matter disclosed herein will be described with reference to exemplary embodiments illustrated in the figures, in which:

FIG. 1 illustrates an example of an apparatus for implementing on-die debug logging logic within an HBM architecture according to the subject matter disclosed herein; and

FIG. 2 illustrates an example method executed by debug logic on the HBM base die of FIG. 1 according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The disclosed HBM base-die architecture improves on contemporary debug and performance-monitoring techniques by relocating key logging and analytics functions into the HBM device itself, rather than relying on host-side instrumentation, boundary-scan access, or manufacturing-only test circuitry. Conventional approaches typically provide limited visibility into transient timing, thermal, PHY, and internal-bus conditions and often require specialized test modes or interruptions to normal memory operation. In contrast, the disclosed base die integrates an on-die debug logging subsystem including a programmable RISC microprocessor, local SRAM configured as a ring buffer, and a DMA engine interconnected via an on-die Network-on-Chip (NoC). This arrangement enables continuous, timestamped collection of fine-grained operational status from HBM controllers, the 3D DRAM PHY/TSV-PHY, die-to-die interconnects, and associated telemetry sources during runtime, followed by autonomous DMA flushing to a reserved memory space accessible to the host. As a result, the system captures otherwise hard-to-observe, short-lived events (e.g., intermittent link errors, queue transients, thermal excursions) with minimal disruption to foreground memory traffic, improving diagnosability, enabling faster root-cause analysis, and supporting runtime optimization of scheduling, reliability, and thermal management in high-bandwidth HBM deployments.

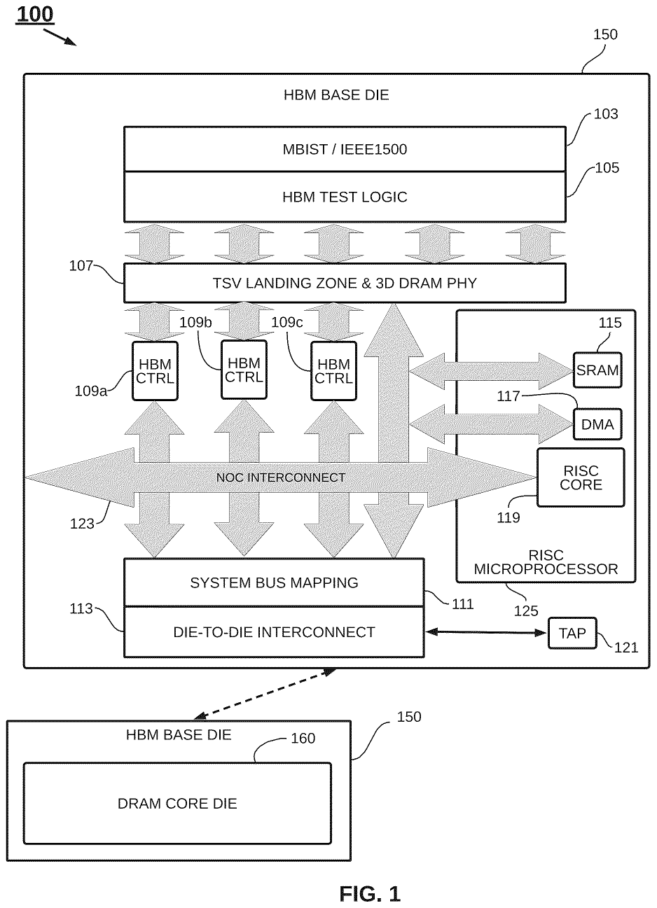

FIG. 1 illustrates an example of an apparatus 100 for implementing on-die debug logging logic within a high-bandwidth memory (HBM) architecture. The apparatus 100 may include an HBM base die 150 coupled to at least one DRAM core die 160 through a physical interface. The physical interface may include a vertical interconnect structure comprising one or more through-silicon vias (TSVs). Together, the base die 150 and the core die 160 may form at least a portion of an HBM stack configured to communicate with an external host device such as a graphics processing unit (GPU) or a central processing unit (CPU).

In some embodiments, the HBM base die 150 integrates a plurality of functional subsystems configured for memory control, testing, debug, and high-speed data exchange. For example, the base die 150 may include a MBIST/IEEE1500 block 103, HBM test logic 105, a TSV landing zone and 3D Dynamic Random-Access Memory (DRAM) physical interface (PHY) 107, multiple HBM controller (HBM CTRL) blocks 109a, 109b, and 109c, a network-on-chip (NoC) interconnect 123, system bus mapping 111 logic, a die-to-die interconnect 113, and an embedded Reduced Instruction Set Computer (RISC) microprocessor 125 incorporating a Static Random-Access Memory (SRAM) 115, a direct memory access (DMA) engine 117, and a RISC core 119. A test access port (TAP) 121 may provide boundary-scan access and integration with external test and debug interfaces.

The MBIST/IEEE1500 block 103 may provide built-in self-test capability for the memory devices of the stack, and may enable standardized test access through IEEE1500 wrapper cells and boundary scan. The HBM test logic 105 may manage functional and parametric testing of HBM channels, illustratively including one or more of loopback testing, training sequences, or interface calibration. These test structures may operate during manufacturing or bring-up, and may be accessible by an on-die debug logic of the apparatus 100 for runtime health monitoring. The on-die debug logic may comprise the RISC microprocessor 125, together with the SRAM 115 and the DMA engine 117, all interconnected through the NoC interconnect 123 inside the HBM base die 150. The TSV landing zone and 3D DRAM PHY 107 may form a physical interface between the base die 150 and the vertically stacked DRAM core die 160. The TSV landing zone may include redistribution layers and contact structures that terminate the TSVs, while the 3D DRAM PHY may contain the electrical transceiver and timing circuitry (TSV-PHY) that drive and receive high-speed data, address, and command signals between the base die and the stacked memory layers. The 3D DRAM PHY 107 may perform one or more of signal training, deskewing, or timing calibration to maintain signal integrity across the vertical interconnect structure.

Each HBM controller block 109a-109c may manage memory channels of the HBM stack, performing command scheduling, refresh control, and data flow management between a host interface and one or more DRAM arrays of the TSV landing zone and 3D DRAM PHY 107. The host interface may comprise an external interconnect between the host (GPU/CPU) and the HBM base die 150, functionally implemented by the input ports of the HBM controller blocks 109a-109c. The HBM controller blocks 109a-109c may be connected through the NoC interconnect 123, which provides a scalable internal bus fabric for command, data, and control traffic. The NoC interconnect 123 may also couple the HBM controller blocks 109a-109c to a debug logging subsystem implemented by the RISC microprocessor 125, enabling the RISC microprocessor 125 to access performance counters and status registers distributed across the HBM base die 150.

The system bus mapping 111 logic may define address regions and routing paths within the NoC 123, allowing the RISC microprocessor 125 and the DMA engine 117 to perform memory-mapped transactions with the HBM controller blocks 109a-109c, the SRAM 115, and/or other on-die components. This mapping enables the DMA engine 117 to transfer debug log data to reserved memory regions of the HBM stack or to host-visible address ranges without interfering with standard operational memory traffic. The die-to-die interconnect 113 may represent horizontal and/or vertical links to adjacent dies or chiplets within a larger package, supporting coherency or communication between multiple HBM stacks or logic dies.

The embedded RISC microprocessor 125 may provide programmable control of the debug logging subsystem. Within the RISC microprocessor 125, the RISC core 119 may execute one or more firmware routines that collect debug information from the HBM controllers 109a-109c, the TSV landing zone and 3D DRAM PHY 107, and sensors or status registers within the DRAM core die 160. The collected information may be time-stamped and temporarily stored in the SRAM 115, which may operate as a circular or ring buffer. When the buffer approaches capacity or at periodic intervals, the DMA engine 117 may autonomously transfer the logged data to a designated memory space defined by the system bus mapping 111. The debug data may include, for example, at least one of controller traffic metrics, PHY signal-integrity statistics, queuing behavior, power telemetry, thermal telemetry, or die-to-die interconnect status.

The TAP 121 may provide a standardized interface (e.g., JTAG or IEEE1500) for external access to at least one of the RISC microprocessor 125, the MBIST/IEEE1500 103, or other testable blocks within the base die 150. Through the TAP 121, manufacturing and field test equipment can initiate diagnostics, access debug registers, or update firmware within the RISC core 119.

The DRAM core die 160 may represent one or more stacked memory layers containing DRAM cell arrays and sense-amplifier circuitry. The DRAM core die 160 may communicate with the base die 150 through the TSV landing zone and 3D DRAM PHY 107 to support high-bandwidth read and write operations coordinated by the HBM controller blocks 109a-109c. Together, the base die 150 and the stacked DRAM core die 160 may form an integrated high-bandwidth memory subsystem with autonomous, on-die debug and performance logging capability.

In terms of industrial applicability, the disclosed high bandwidth memory architecture of FIG. 1 may be applied in graphics processing units (GPUs), artificial intelligence accelerators, network processors, or other high-performance computing systems requiring dense, high-throughput memory modules. The described architecture of FIG. 1 may provide one or more of the following technical advantages:
Scalable parallel access across multiple stacked DRAM dies;
Improved system-bus integration and adaptive mapping;
Redundant TSV management for yield and reliability;
Built-in test and debug access through standardized interfaces; and
Compatibility with HBM and future-generation stacked memory protocols.

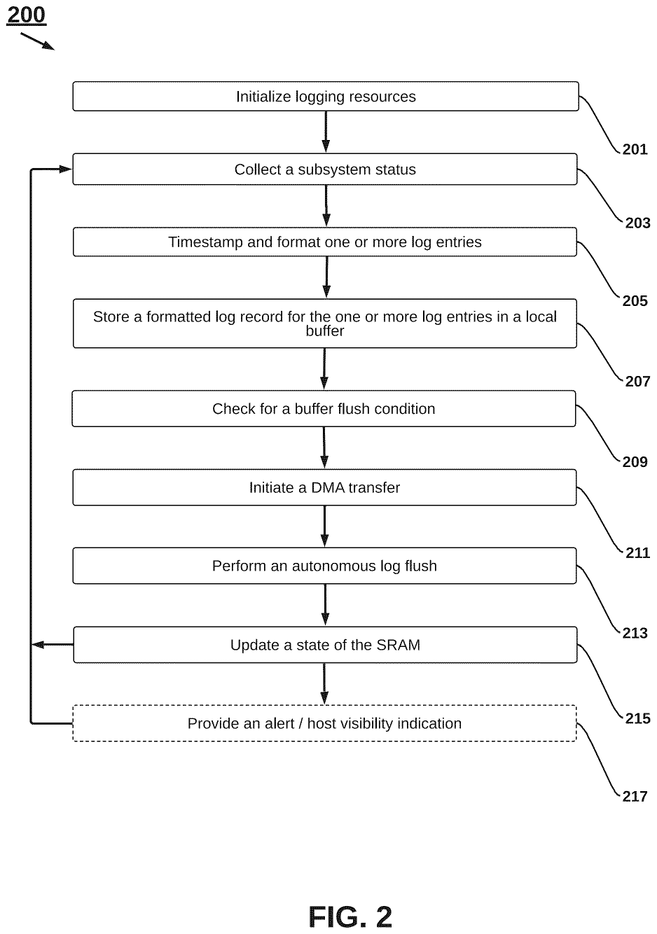

FIG. 2 illustrates an example method 200 executed by debug logic on the HBM base die 150 of FIG. 1 to acquire timestamped operational data from internal subsystems, buffer the data locally in on-die SRAM 115, and autonomously flush the buffered data via the DMA engine 117 to a reserved memory region for host retrieval, all without interrupting standard operational HBM traffic. The on-die debug logic may comprise the RISC microprocessor 125, together with the SRAM 115 and the DMA engine 117, all interconnected through the NoC interconnect 123 inside the HBM base die 150. The method of FIG. 2 may be implemented, for example, as firmware executing on the RISC microprocessor 125 (FIG. 1) and/or as control logic associated with the DMA 117 and system bus mapping 111.

The method of FIG. 2 commences at block 201 where logging resources may be initialized. The RISC microprocessor 125 (FIG. 1) may initialize a local debug-logging state. This initialization operation may include configuring the SRAM 115 as a ring buffer, establishing write and read pointers for that buffer, setting up one or more timestamp counters or clocks, and programming DMA destination addresses via the system bus mapping 111. During this operation, the RISC microprocessor 125 may also register which telemetry sources are to be monitored (for example, which of HBM CTRL 109a/109b/109c, TSV landing zone/3D DRAM PHY 107, die-to-die interconnect 113, thermal/power sensors, etc. will be sampled).

At block 203 of FIG. 2, a subsystem status may be collected. At defined sample intervals, or in response to an event trigger, the RISC core 119 (FIG. 1) may read status information from one or more on-die subsystems of the HBM base die 150 via the NoC interconnect 123. The collected status may include any of:
traffic utilization, queue depth, scheduling state, or refresh activity from the HBM controller blocks 109a-109c;
link integrity, timing calibration results, or error counters from the TSV landing zone and 3D DRAM PHY 107 (including TSV-PHY information);
health/telemetry of the die-to-die interconnect 113;
power and thermal readings associated with the HBM base die 150 and/or DRAM core die 160; or
memory bank scheduling statistics and queuing order within the memory channels of the HBM stack.
   In some embodiments, certain information from the DRAM core die 160 is surfaced to readable registers in the base die through the 3D DRAM PHY 107. The RISC microprocessor 125 may obtain those values as part of this collection step.

At block 205 of FIG. 2, a timestamping and formatting of one or more log entries may be performed. The RISC microprocessor 125 (FIG. 1) may associate each collected set of subsystem status information (from FIG. 2, block 203) with a timestamp. The timestamp may be generated using a counter or reference clock within the HBM base die 150 (FIG. 1). The RISC microprocessor 125 may format the sampled data and timestamp into a log record. In some embodiments, the log record may include a source identifier (for example, which HBM controller or which PHY instance), and/or a severity or flag field indicating whether any threshold condition (thermal limit, retry count, queue depth overrun, etc.) was crossed.

At block 207 of FIG. 2, a formatted log record for the one or more log entries may be stored in a local buffer. For example, the formatted log record may be written into the SRAM 115 (FIG. 1). The SRAM 115 may be arranged as a circular (ring) buffer so that newer records overwrite the oldest records after the buffer becomes full. The RISC microprocessor 125 may update the ring buffer write pointer accordingly. Because the SRAM 115 is on the same HBM base die 150 and connected through the NoC interconnect 123, this write may comprise a low-latency local store that does not require host intervention. In some embodiments, the SRAM 115 (or a designated region thereof) is configured as a debug logging buffer, such as a circular (ring) buffer, for storing timestamped log entries generated by the RISC microprocessor 125. Accordingly, references herein to a ‘debug logging buffer’ refer to SRAM 115 configured as the circular buffer used to store the log entries prior to DMA flushing.

At block 209 of FIG. 2, a buffer flush condition may be checked. The RISC microprocessor 125 (FIG. 1) and/or accompanying hardware logic may determine whether the SRAM 115 buffer should be flushed. The flush condition may be met if:
the ring buffer in the SRAM 115 has reached or exceeded a fill threshold;
a periodic timer or heartbeat interval has expired;
a specific fault or debug event has been detected (for example, excessive TSV link errors reported by the 3D DRAM PHY 107, or a thermal excursion).
   In some embodiments, determining that the flush condition is satisfied may be based on at least one of a fill level or a timer associated with the debug logging buffer. If no flush condition is met, the method of FIG. 2 may loop back to block 203 to continue periodic sampling. If the flush condition is met, the flow proceeds to block 211.

At block 211, a DMA transfer may be initiated. The RISC microprocessor 125 (FIG. 1) may program the DMA engine 117 with the source address range of the accumulated log data in the SRAM 115 and a destination address that corresponds to a reserved memory space. The reserved memory space may reside in a protected region of the HBM address map that is accessible to the host for later retrieval, or in a dedicated diagnostic region mapped by the system bus mapping 111 for software on the host processor. Once configured, the DMA engine 117 may begin transferring the log data without requiring the RISC core 119 to copy the bytes manually.

At block 213 of FIG. 2, an autonomous log flush may be performed. The DMA engine 117 (FIG. 1) may issue one or more memory write transactions over the NoC interconnect 123 and through the system bus mapping 111 to push the log records out of the SRAM 115 and into the reserved memory space. This bulk transfer can occur while standard operational memory transactions continue to flow through HBM controllers 109a-109c, because the DMA engine 117 behaves as another on-die bus master rather than hijacking the host's external interface. Accordingly, block 213 (FIG. 2) may represent an HBM traffic interface configured to distinguish and manage different classes of transactions entering the memory apparatus. In operation, the interface may receive transaction requests from the NOC interconnect 123 (FIG. 1) and classify them as either standard operational memory transactions or auxiliary transactions such as test, calibration, or maintenance operations. For standard operational memory transactions, block 213 (FIG. 2) may direct command, address, and data fields to the HBM controllers 109a-109c (FIG. 1), where they are decoded into corresponding bank, row, and column access operations across the stacked DRAM dies 160. By contrast, auxiliary transactions including built-in self-test (BIST), TSV continuity testing, or debug access through the TAP 12, may be routed to internal test logic blocks such as the MBIST/IEEE 1500 interface 103 or the HBM test logic 105. By separating standard operational traffic from auxiliary control traffic, block 213 (FIG. 2) may ensure that foreground memory accesses proceed without interference from background maintenance or diagnostic processes, maintaining deterministic timing and bandwidth utilization for the HBM channel.

At block 215, the state of the SRAM 115 (FIG. 1) may be updated. After completion of the DMA transfer, the DMA engine 117 may signal completion (e.g., via an interrupt or status bit) to the RISC microprocessor 125. In response, the RISC microprocessor 125 may advance or reset the ring buffer read pointer of the SRAM 115 so that a freed SRAM region is now available for new log entries. At this point, the ring buffer of the SRAM 115 can start accumulating fresh logs again without losing continuity.

At optional block 217 of FIG. 2, an alert/host visibility may be provided. In some embodiments, if the flushed data contained one or more “critical” markers, such as abnormal die-to-die interconnect 113 error rates, PHY training instability at the TSV landing zone and 3D DRAM PHY 107, or an over-temperature event, the RISC microprocessor 125 may post an alert. This alert may be exposed via the TAP 121, a debug/status register that is host-readable, or a sideband signal to the host interface 101. This allows a host GPU/CPU or test probe to know not just that data is available, but that something noteworthy happened. After buffer maintenance and any optional alerting, the method of FIG. 2 may loop back to block 203 to continue monitoring, logging, and flushing in a continuous cycle during steady-state runtime of the HBM stack.

In some embodiments, the RISC microprocessor 125 and RISC core 119 (FIG. 1) drive the operations of blocks 201, 203, 205, 207, 209, 211, 215 and 217 (FIG. 2). The SRAM 115 (FIG. 1) may be the ring buffer used in the operations of blocks 211 and 213 (FIG. 2). The DMA engine 117 (FIG. 1) may perform the autonomous flushing in the operations of blocks 211 and 213 (FIG. 2). The HBM controllers 109a-109c (FIG. 1) may function as a primary source of runtime counters, queues, and traffic stats in the operation of block 203 (FIG. 2). The TSV landing zone and 3D DRAM PHY 107 (FIG. 1) may function as a source of physical-link integrity, timing, and TSV-PHY status sampled in the operation of block 203 (FIG. 2). The die-to-die interconnect 113 (FIG. 1) may supply inter-die link health, lane error, and/or coherency status sampled in the operation of block 203 (FIG. 2). The system bus mapping 111 (FIG. 1) is the entity that makes the DMA destination “real”. In the operations of blocks 211 and 213 (FIG. 2), the system bus mapping 111 (FIG. 1) enables the DMA engine 117 to write logs into a reserved memory range that the host can later read, without corrupting standard operational HBM traffic. The TAP 121 enables outside equipment (or firmware on a host) to observe alerts and/or to retrieve diagnostic information in the operation of block 217 (FIG. 2).

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method of operating a high-bandwidth memory (HBM) base die including a near-memory computing subsystem, the method comprising:
initializing, by a Reduced Instruction Set Computer (RISC) microprocessor on the HBM base die, a debug logging buffer in an on-die static random-access memory (SRAM);
collecting, by the RISC microprocessor, operational status information from one or more subsystems of the HBM base die, the one or more subsystems including at least one HBM controller, a 3D DRAM physical interface (PHY), and a die-to-die interconnect;
timestamping the collected operational status information and storing the timestamped information as log entries in the debug logging buffer;
determining that a flush condition is satisfied based on the debug logging buffer; and
initiating, responsive to the flush condition being satisfied, a direct-memory-access (DMA) transfer from the debug logging buffer to a reserved memory space accessible to a host device.

2. The method of claim 1, wherein the reserved memory space comprises a protected region of the HBM address map defined by system bus mapping circuitry on the HBM base die.

3. The method of claim 1, wherein collecting the operational status information comprises reading performance counters, queue depths, or thermal sensor values via a network-on-chip (NoC) interconnect coupling the RISC microprocessor to the one or more subsystems.

4. The method of claim 1, further comprising:
detecting, by the RISC microprocessor, an error or threshold event based on the collected operational status information; and
generating an alert signal accessible through a test access port (TAP) of the HBM base die.

5. The method of claim 1, wherein the DMA transfer is performed concurrently with normal memory-access operations of the one or more HBM controllers.

6. The method of claim 1, further comprising formatting each log entry with a subsystem identifier and a severity flag before storage in the debug logging buffer.

7. The method of claim 1, wherein the debug logging buffer is implemented as a circular buffer, and the RISC microprocessor resets a write pointer after completion of the DMA transfer.

8. The method of claim 1, wherein the operational status information includes at least one of: (a) HBM controller traffic statistics, (b) PHY training or deskewing data, (c) TSV-PHY link integrity metrics, (d) voltage and/or current telemetry for each of a plurality of voltage domains, (e) thermal telemetry for at least one predetermined hot-spot location, (f) die-to-die interconnect coherency status, (g) error-correcting code/detection telemetry from the on-die SRAM of the HBM base die, or (h) HBM memory bit error correction and detection telemetry.

9. The method of claim 1, further comprising providing host-visible access to the transferred log data through a host interface of the HBM base die.

10. The method of claim 1, wherein the RISC microprocessor continues periodic collection of operational status information during the DMA transfer to maintain continuous logging.

11. A high-bandwidth memory (HBM) base die comprising:
a plurality of HBM controller blocks each configured to manage command scheduling and data flow between a host interface and one or more memory devices of an HBM stack;
a 3D DRAM physical interface (PHY) coupled to the one or more memory devices through a plurality of through-silicon vias (TSVs);
a die-to-die interconnect configured to communicate with an adjacent die within a multi-die package;
a network-on-chip (NoC) interconnect configured to couple internal subsystems of the HBM base die; and
on-die debug logic comprising:
a Reduced Instruction Set Computer (RISC) microprocessor coupled to the NoC interconnect;
a static random-access memory (SRAM) coupled to the RISC microprocessor and configured as a circular log buffer; and
a direct-memory-access (DMA) engine configured to transfer debug log data from the SRAM to a reserved memory region defined by a system bus mapping circuit;
wherein the RISC microprocessor is configured to collect operational status information from one or more of the HBM controller blocks, the 3D DRAM PHY, and the die-to-die interconnect, timestamp the collected information, and store timestamped log entries in the SRAM.

12. The HBM base die of claim 11, wherein the system bus mapping circuit defines an address range in the HBM address space reserved for debug data accessible to a host processor.

13. The HBM base die of claim 11, wherein the RISC microprocessor is further configured to detect a buffer-flush condition based on a fill threshold or a timer, and to initiate the DMA transfer in response to the buffer-flush condition.

14. The HBM base die of claim 11, wherein the DMA engine is configured to perform the transfer of the debug log data concurrently with normal memory transactions of the HBM controller blocks.

15. The HBM base die of claim 11, wherein the RISC microprocessor is further configured to format each log entry with a subsystem identifier and a timestamp prior to storage in the SRAM.

16. The HBM base die of claim 11, wherein the RISC microprocessor continues to collect operational status information while the DMA engine transfers previously stored log data.

17. The HBM base die of claim 11, wherein the operational status information includes at least one of: (a) traffic statistics from an HBM controller block, (b) TSV-PHY timing or link-integrity information, (c) die-to-die interconnect status, or (d) power or thermal telemetry from sensors within the HBM base die.

18. The HBM base die of claim 11, wherein the RISC microprocessor is further configured to generate an alert condition when a parameter of the operational status information exceeds a predetermined threshold.

19. The HBM base die of claim 18, wherein the alert condition is output through a test access port (TAP) of the HBM base die or as a status flag accessible to the host interface.

20. The HBM base die of claim 11, wherein the debug logic is implemented at least partially in firmware stored in the SRAM and executed by the RISC microprocessor.
